(19) United States
(12) Patent Application Publication
(10) Pub. No.: US 2025/0109250 A1
(43) Pub. Date: Apr. 3, 2025

(54) RESIN COMPOSITION, CURED OBJECT, SHEET, LAYERED PRODUCT, AND PRINTED WIRING BOARD

(71) Applicant: Resonac Corporation, Tokyo (JP)

(72) Inventors: Kitaru SATO, Tokyo (JP); Tetsuya IMAI, Tokyo (JP)

(21) Appl. No.: 18/710,065

(22) PCT Filed: Nov. 16, 2022
(86) PCT No.: PCT/JP2022/042567

§ 371 Date: May 14, 2024

(30) Foreign Application Priority Data
Nov. 18, 2021 (JP) 2021-187738

(51) Int. Cl. C08G 73/12; C08F 283/04; C08J 7/04; C08K 5/14

(52) U.S. Cl. CPC C08G 73/12; C08F 283/04; C08J 7/0423; C08K 5/14; C08J 2351/08

(57) ABSTRACT

A resin composition including a maleimide resin (A) obtained by reacting a tetracarboxylic acid dianhydride (a1), a diamine (a2), and maleic anhydride (a3), in which the tetracarboxylic acid dianhydride (a1) contains at least one of a compound represented by the following Formula (1), a compound represented by the following Formula (2), and a compound represented by the following Formula (6), and the diamine (a2) contains a dimer diamine and a second diamine other than a dimer diamine:

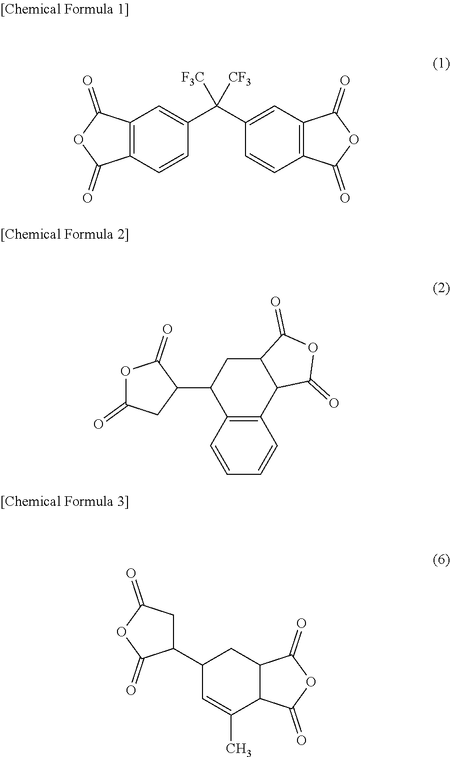 [SMILES: O=C1OC(=O)c2cc(C(c3ccc4c(c3)C(=O)OC4=O)(C(F)(F)F)C(F)(F)F)ccc21 ; O=C1CC(C2CC3C(=O)OC(=O)C3c3ccccc32)C(=O)O1 ; CC1=CC(C2CC(=O)OC2=O)CC2C(=O)OC(=O)C12]

### TECHNICAL FIELD

The present disclosure relates to a resin composition, a cured product, a sheet, a laminated body, and a printed wiring board.

### BACKGROUND ART

Printed wiring boards and multilayer wiring boards using those printed wiring boards are used in manufactured products such as mobile communication equipment such as mobile phones and smartphones, base station devices thereof, network-related electronic equipment such as servers and routers, and large-sized computers.

In recent years, high-frequency electrical signals are used in those manufactured products in order to transmit and process large volumes of information at high speed; however, since high-frequency signals are highly susceptible to attenuation, insulating materials having excellent dielectric characteristics are required as insulating material for use in the above-described printed wiring boards, multilayer wiring boards, and the like in order to suppress transmission loss.

Regarding the above-described insulation materials, the epoxy resin compositions disclosed in Patent Literatures 1 to 3 are known. This Patent Literature 1 discloses that an epoxy resin composition containing an epoxy resin, an active ester compound, and a triazine-containing cresol novolac resin is effective for lowering the dielectric loss tangent. Furthermore, Patent Literatures 2 and 3 disclose that a resin composition containing an epoxy resin and an active ester compound as essential components can form a cured product having a low dielectric loss tangent and is useful as an insulating material. However, it has been found that these epoxy resin compositions are not satisfactory for high-frequency band applications.

On the other hand, it has been reported in Patent Literature 4 that a resin film formed from a resin composition containing a maleimide resin having a long-chain alkyl group as a non-epoxy-based material and a curing agent has excellent dielectric characteristics (having a low dielectric constant and a low dielectric loss tangent).

However, a maleimide resin composed only of a long-chain alkyldiamine has a problem of having a low Tg and a low elastic modulus.

### CITATION LIST

### Patent Literature

Patent Literature 1: Japanese Unexamined Patent Publication No. 2011-132507
Patent Literature 2: Japanese Unexamined Patent Publication No. 2015-101626
Patent Literature 3: Japanese Unexamined Patent Publication No. 2017-210527
Patent Literature 4: International Publication WO 2016/114287

### SUMMARY OF INVENTION

### Technical Problem

Thus, it is an object of the present disclosure to provide a resin composition capable of forming a cured product having a higher elastic modulus and a higher Tg while sufficiently maintaining a low dielectric constant and a low dielectric loss tangent. It is another object of the present disclosure to provide a cured product, a sheet, a laminated body, and a printed wiring board, all of which use the above-described resin composition.

### Solution to Problem

The inventors of the present invention conducted a thorough investigation in order to solve the above-described problems, and as a result, the inventors found that with regard to a maleimide resin (A) obtained by reacting a tetracarboxylic acid dianhydride (a1), a diamine (a2), and maleic anhydride (a3), when predetermined components are used as the tetracarboxylic acid dianhydride (a1) and the diamine (a2), a cured product having a higher elastic modulus and a higher Tg while sufficiently maintaining a low dielectric constant and a low dielectric loss tangent can be formed, thus completing the present invention.

That is, the present disclosure provides the following inventions.

[1] A resin composition including a maleimide resin (A) obtained by reacting a tetracarboxylic acid dianhydride (a1), a diamine (a2), and maleic anhydride (a3), in which the tetracarboxylic acid dianhydride (a1) contains at least one of a compound represented by the following Formula (1), a compound represented by the following Formula (2), and a compound represented by the following Formula (6), and the diamine (a2) contains a dimer diamine and a second diamine other than a dimer diamine:

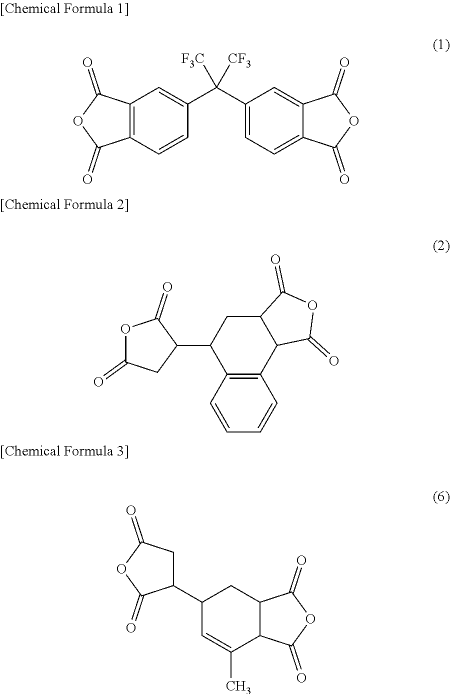 [SMILES: O=C1OC(=O)c2cc(C(c3ccc4c(c3)C(=O)OC4=O)(C(F)(F)F)C(F)(F)F)ccc21 ; O=C1CC(C2CC3C(=O)OC(=O)C3c3ccccc32)C(=O)O1 ; CC1=CC(C2CC(=O)OC2=O)CC2C(=O)OC(=O)C12]

[2] The resin composition according to the above-described [1], in which the second diamine includes at least one selected from the group consisting of 1,3-diaminopropane, norbornanediamine, 4,4′-methylenedianiline, and 1,3-bis[2-(4-aminophenyl)-2-propyl]benzene.
[3] The resin composition according to the above-described [1] or [2], in which the dimer diamine includes at least one of a compound represented by the following General Formula (3) and a compound represented by the following General Formula (4):

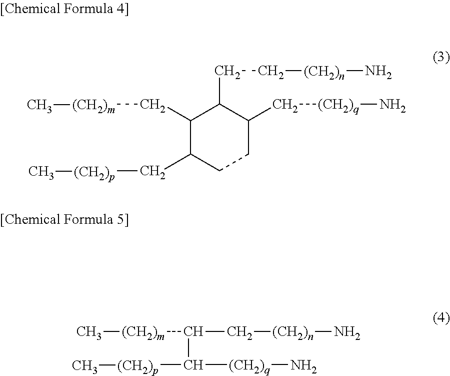

wherein in Formula (3) and Formula (4), n, n, p, and q each represent an integer of 1 or greater selected such that n+n=6 to 17 and p+q=8 to 19; and a bond indicated by a broken line means a carbon-carbon single bond or a carbon-carbon double bond, provided that in a case where the bond indicated by a broken line is a carbon-carbon double bond, Formula (3) and Formula (4) form structures in which the number of hydrogen atoms bonded to each carbon atom constituting the carbon-carbon double bond is smaller by 1 than the number indicated in Formula (3) and Formula (4).
[4] The resin composition according to any one of the above-described [1] to [3], in which the maleimide resin (A) has a weight average molecular weight of 3000 to 25000.
[5] A cured product of the resin composition according to any one of the above-described [1] to [4].
[6] A sheet including the resin composition according to any one of the above-described [1] to [4] and a base material.
[7] The sheet according to the above-described [6], in which the base material is an organic base material.
[8] The sheet according to the above-described [6], in which the base material is an inorganic base material.
[9] A laminated body obtained by allowing another base material to be thermocompression bonded to an adhesive surface of the sheet according to any one of the above-described [6] to [8].
[10] A printed wiring board obtained by using the sheet according to any one of the above-described [6] to [8].
[11] A printed wiring board obtained by using the laminated body according to the above-described [9].

### Advantageous Effects of Invention

According to the present disclosure, a resin composition capable of forming a cured product having a higher elastic modulus and a higher Tg while sufficiently maintaining a low dielectric constant and a low dielectric loss tangent, as well as a cured product, a sheet, a laminated body, and a printed wiring board, all of which use the resin composition, can be provided.

The resin composition (adhesive composition) of the present disclosure can reduce both the dielectric constant and the dielectric loss tangent (hereinafter, the two may be collectively referred to as “dielectric characteristics”) and has particularly excellent low dielectric characteristics in the high-frequency band. In addition, a cured product (adhesive layer) obtained from the resin composition has a high elastic modulus and a high Tg, and therefore, the resin composition is useful not only as an adhesive used for the production of printed circuit boards (buildup substrates, flexible printed wiring boards, and the like) and copper-clad boards for printed wiring boards, but also as a semiconductor interlayer material, a coating agent, a resist ink, a conductive paste, an electrically insulating material, or the like.

### DESCRIPTION OF EMBODIMENTS

Hereinafter, embodiments of the present disclosure will be described in detail.

### <Resin Composition>

A resin composition of the present embodiment includes a maleimide resin (A) (hereinafter, also referred to as “component (A)”) obtained by reacting a tetracarboxylic acid dianhydride (a1) (hereinafter, also referred to as “component (a1)”), a diamine (a2) (hereinafter, also referred to as “component (a2)”), and maleic anhydride (a3) (hereinafter, also referred to as “component (a3)”). The resin composition of the present embodiment may further include a polymerization initiator (B) (hereinafter, also referred to as “component (B)”). In addition, the resin composition of the present embodiment may further include an organic solvent (C) (hereinafter, also referred to as “component (C)”).

### (Component (A): Maleimide Resin)

The component (A) can be obtained by reacting the component (a1), the component (a2), and the component (a3). The component (A) may have a plurality of maleimide groups in the molecule. The component (A) may be a bismaleimide resin.

The component (a1) contains at least one of a compound represented by the following Formula (1), a compound represented by the following Formula (2), and a compound represented by the following Formula (6).

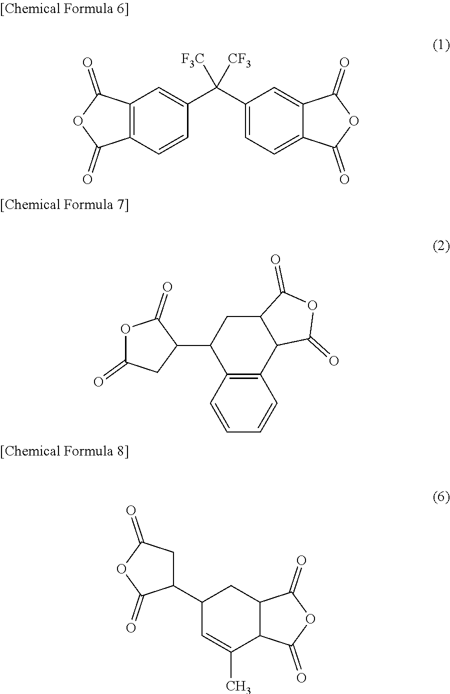 [SMILES: O=C1OC(=O)c2cc(C(c3ccc4c(c3)C(=O)OC4=O)(C(F)(F)F)C(F)(F)F)ccc21 ; O=C1CC(C2CC3C(=O)OC(=O)C3c3ccccc32)C(=O)O1 ; CC1=CC(C2CC(=O)OC2=O)CC2C(=O)OC(=O)C12]

The compound represented by Formula (1) is 4,4′-(hexafluoroisopropylidene) diphthalic anhydride. The compound represented by Formula (2) is 1,3,3a,4,5,9b-hexahydro-5(tetrahydro-2,5-dioxo-3-furanyl)naphtho[1,2-C]furan-1,3-dione. The compound represented by Formula (6) is 5-(2,5-dioxotetrahydrofuryl)-3-methyl-3-cyclohexene-1,2-dicarboxylic acid anhydride. By using these compounds as the component (a1), the elastic modulus and Tg of the cured product can be improved while sufficiently maintaining the low dielectric constant and low dielectric loss tangent of the cured product.

The component (a1) may include another tetracarboxylic acid dianhydride other than the compounds represented by General Formulas (1), (2), and (6). As the other tetracarboxylic acid dianhydride, compounds known as raw materials of polyimide can be used.

Examples of the other tetracarboxylic acid dianhydride include pyromellitic anhydride, 4,4′-oxydiphthalic dianhydride, 3,3′,4,4′-diphenylsulfonetetracarboxylic acid dianhydride, 3,3′,4,4′-biphenyltetracarboxylic acid dianhydride, 3,3′,4,4′-benzophenonetetracarboxylic acid dianhydride, 4,4′-(4,4′-isopropylidenediphenoxy)diphthalic anhydride, 4,4′-(hexafluoroisopropylidene)diphthalic anhydride, 1,2,3,4-butanetetracarboxylic acid dianhydride, 1,2,4,5-cyclohexanetetracarboxylic acid dianhydride, 1,3,3a,4,5,9b-hexahydro-5(tetrahydro-2,5-dioxo-3-furanyl)naphtho[1,2-C]furan-1,3-dione, 1,2,3,4-cyclobutanetetracarboxylic acid dianhydride, 1,2,3,4-cyclopentanetetracarboxylic acid dianhydride, 1,2,3,4-tetramethyl-1,2,3,4-cyclobutanetetracarboxylic acid dianhydride, bicyclo[2.2.2]oct-7-ene-2,3,5,6-tetracarboxylic acid dianhydride, bicyclo[2.2.2]octane-2,3,5,6-tetracarboxylic acid 2,3:5,6-dianhydride, 1,4-phenylene bis(1,3-dioxo-1,3-dihydroisobenzofuran-5-carboxylate), 9,9-bis(3,4-dicarboxyphenyl)fluorene dianhydride, 9,9-bis[4-(3,4-dicarboxyphenoxy)phenyl]fluorene dianhydride, 4,4′-(ethyne-1,2-diyl)diphthalic anhydride, dicyclohexyl-3,4,3′,4′-tetracarboxylic acid dianhydride, 3,4′-oxydiphthalic anhydride, and 3,4′-biphthalic anhydride. These can be used singly or in combination of two or more kinds thereof.

The total content of the compound represented by Formula (1), the compound represented by Formula (2), and the compound represented by Formula (6) in the component (a1) may be 50 mol % or more, may be 70 mol % or more, or may be 100 mol %, based on the total amount of the component (a1), from the viewpoint of improving the elastic modulus and Tg of the cured product.

The component (a2) contains a dimer diamine (first diamine) and a second diamine other than a dimer diamine.

The dimer diamine is, for example, a compound derived from a dimer acid, which is a dimer of an unsaturated fatty acid such as oleic acid, as described in Japanese Unexamined Patent Publication No. H9-12712. In the present embodiment, any known dimer diamine can be used without particular limitation; however, for example, a dimer diamine represented by the following General Formula (3) and/or General Formula (4) is preferred.

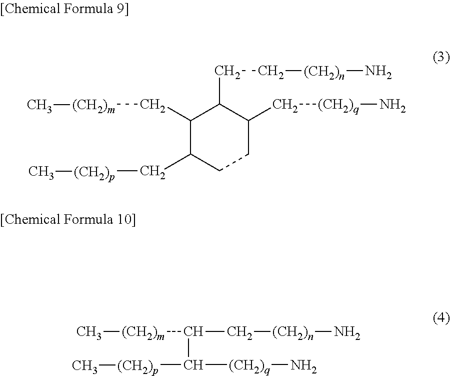

wherein in Formula (3) and Formula (4), m, n, p, and q each represent an integer of 1 or greater selected such that m+n=6 to 17 and p+q=8 to 19; and a bond indicated by a broken line means a carbon-carbon single bond or a carbon-carbon double bond, provided that in a case where the bond indicated by a broken line is a carbon-carbon double bond, Formula (3) and Formula (4) form structures in which the number of hydrogen atoms bonded to each carbon atom constituting the carbon-carbon double bond is smaller by 1 than the number indicated in Formula (3) and Formula (4).

As the dimer diamine, from the viewpoints of the solubility in organic solvents, heat resistance, heat-resistant adhesiveness, low viscosity, and the like, a compound represented by the above-described General Formula (4) is preferred, and a compound represented by the following Formula (5) in particular is preferred.

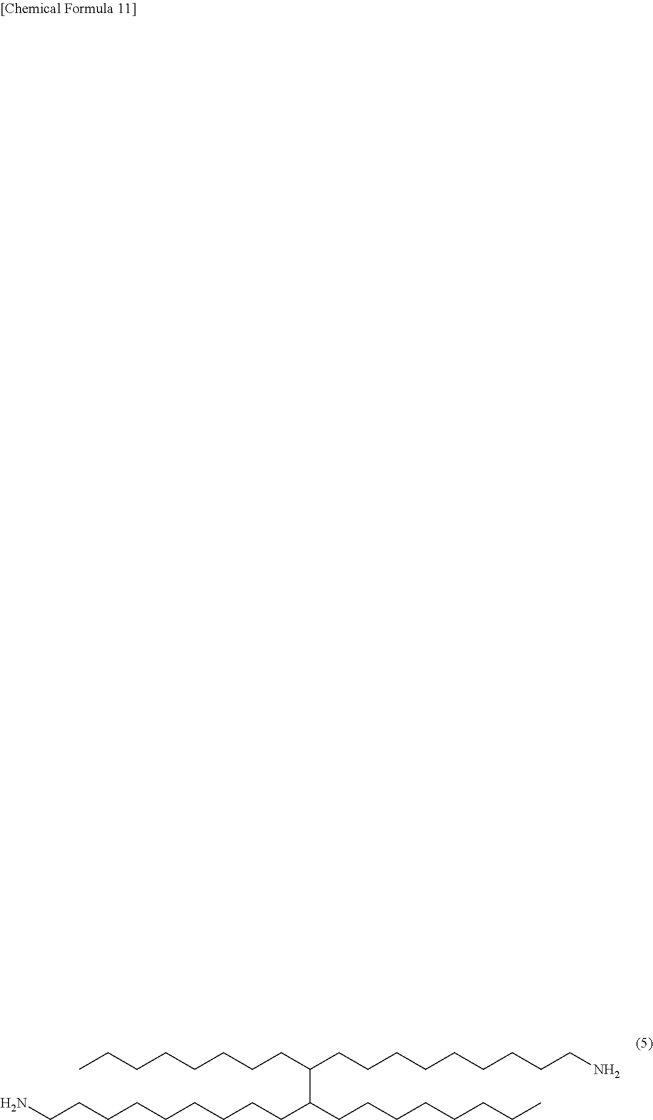

Examples of a commercially available product of the dimer diamine include PRIAMINE 1075 and PRIAMINE 1074 (all manufactured by Croda Japan K.K.). These can be used singly or in combination of two or more kinds thereof.

The second diamine is a diamine that does not correspond to the above-mentioned dimer diamine. Examples of the second diamine include 1,3-diaminopropane, norbornanediamine, 4,4′-methylenedianiline, 1,3-bis[2-(4-aminophenyl)-2-propyl]benzene, 1,4-bis[2-(4-aminophenyl)-2-propyl]benzene, 4,4′-diamino-2,2′-bis(trifluoromethyl)biphenyl, 2,2-bis[4-(4-aminophenoxy)phenyl]hexafluoropropane, 9,9-bis(4-aminophenyl)fluorene, 9,9-bis[4-(4-aminophenoxy)phenyl]fluorene, 1,3-bis(aminomethyl)cyclohexane, 1,4-bis(aminomethyl)cyclohexane, bis(aminomethyl)norbornane, 4,4′-(hexafluoroisopropylidene)dianiline, 3(4),8(9)-bis(aminomethyl)tricyclo[5.2.1.02,6]decane, 1,3-cyclohexanediamine, 1,4-cyclohexanediamine, isophorone diamine, 4,4′-methylenebis(cyclohexylamine), 4,4′-methylenebis(2-methylcyclohexylamine), 1,1-bis(4-aminophenyl)cyclohexane, 2,7-diaminofluorene, 4,4′-ethylenedianiline, 4,4′-methylenebis(2,6-diethylaniline), 4,4′-methylenebis(2-ethyl-6-methylaniline), 2,2-bis[4-(4-aminophenoxy)phenyl]propane, bis[4-(4-aminophenoxy)phenyl]methane, 4,4′-bis(4-aminophenoxy)biphenyl, bis[4-(4-aminophenoxy)phenyl]ether, bis[4-(4-aminophenoxy)phenyl] ketone, 1,3-bis(4-aminophenoxy)benzene, 1,4-bis(4-aminophenoxy)benzene, 2,2′-dimethylbiphenyl-4,4′-diamine, (4,4′-diamino)diphenyl ether, (3,3′-diamino)diphenyl ether, para-phenylenediamine, ortho-phenylenediamine, meta-phenylenediamine, 2,2′-dimethylbiphenyl-4,4′-diamine, bis[4-(3-aminophenoxy)phenyl]sulfone, bis[4-(4-aminophenoxy)phenyl]sulfone, and 2-methyl-1,5-diaminopentane. These can be used singly or in combination of two or more kinds thereof.

By using a dimer diamine as the diamine, the dielectric characteristics of the cured product can be lowered. On the other hand, in a case where only a dimer diamine is used as the diamine, the elastic modulus and Tg of the cured product are decreased. In contrast, the elastic modulus and Tg of the cured product can be improved by using the second diamine in combination with the dimer diamine.

The molar ratio of the second diamine (number of moles of the second diamine/(number of moles of the dimer diamine+number of moles of the second diamine)) in the component (a2) may be 20 to 70 mol % or may be 30 to 50 mol %. When this ratio is 20 mol % or more, the elastic modulus and Tg of the cured product can be further improved, and when this ratio is 70 mol % or less, the dielectric characteristics of the cured product can be further lowered.

The component (A) can be produced by various known methods. For example, first, the component (a1) and the component (a2) are subjected to a polyaddition reaction at a temperature of about 60 to 120° C., and preferably 70 to 90° C., usually for about 0.1 to 2 hours, and preferably 0.1 to 1.0 hours. Next, the obtained polyaddition product is further subjected to an imidization reaction, that is, a dehydration ring-closing reaction, at a temperature of about 80 to 250° C., and preferably 100 to 200° C., for about 0.5 to 30 hours, and preferably 0.5 to 10 hours. Subsequently, the resultant of the dehydration ring-closing reaction and the component (a3) are subjected to a maleimidation reaction, that is, a dehydration ring-closing reaction, at a temperature of about 60 to 250° C., and preferably 80 to 200° C., for about 0.5 to 30 hours, and preferably 0.5 to 10 hours, to obtain the intended component (A).

Incidentally, in the imidization reaction or the maleimidation reaction, various known reaction catalysts, dehydrating agents, and organic solvents that will be described below can be used. Examples of the reaction catalysts include aliphatic tertiary arines such as triethylamine; aromatic tertiary arines such as dimethylaniline; heterocyclic tertiary arines such as pyridine, picoline, and isoquinoline; and organic acids such as methanesulfonic acid and para-toluenesulfonic acid monohydrate. These can be used singly or in combination of two or more kinds thereof. Examples of the dehydrating agents include aliphatic acid anhydrides such as acetic anhydride; and aromatic acid anhydrides such as benzoic anhydride. These can be used singly or in combination of two or more kinds thereof.

In addition, the component (A) can be purified by various known methods, and purity can be increased. For example, first, the component (A) dissolved in the organic solvent and pure water is fed into a separatory funnel. Next, the separatory funnel is shaken and left to stand still. Subsequently, after an aqueous layer and an organic layer are separated, the component (A) can be purified by collecting only the organic layer.

The molecular weight of the component (A) can be controlled by the numbers of moles of the component (a1) and the component (a2), and as the number of moles of the component (a1) is smaller than the number of moles of the component (a2), the molecular weight can be made smaller. For the purpose of allowing the effects of the present disclosure to be easily achieved, usually, the ratio [number of moles of component (a1)]/[number of moles of component (a2)] may be about 0.30 to 0.85, and preferably in the range of 0.50 to 0.80.

From the viewpoints of the solubility in solvents and the heat resistance, the molecular weight of the component (A) is preferably 3000 to 25000, and more preferably 7000 to 20000, as the weight average molecular weight. When the weight average molecular weight is 25000 or less, the solubility in organic solvents is satisfactory, and when the weight average molecular weight is 3000 or more, the effect of improving heat resistance tends to be sufficiently obtained.

Regarding the component (A), one kind thereof can be used alone, or two or more kinds thereof can be used in combination.

### (Component (B): Polymerization Initiator)

Specific examples of the component (B) include an organic peroxide, an imidazole compound, a phosphine compound, and a phosphonium salt compound. These can be used singly or in combination of two or more kinds thereof. Above all, an imidazole compound in particular is preferable for having an excellent function as a polymerization initiator and being excellent even in terms of low dielectric characteristics.

Examples of the organic peroxide include methyl ethyl ketone peroxide, methyl cyclohexanone peroxide, methyl acetoacetate peroxide, acetylacetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, n-butyl-4,4-bis(t-butylperoxy)valerate, 2,2-bis(t-butylperoxy)butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy)hexane, α,α′-bis(t-butylperoxy)diisopropylbenzene, t-butylcumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate, α,α′-bis(neodecanoylperoxy)diisopropylbenzene, cumyl peroxyneodecanoate, 1,1,3,3-tetramethylbutyl peroxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 2,5-dimethyl-2,5-bis(2-ethylhexanoylperoxy)hexane, 1,1,3,3-tetramethylbutyl peroxy-2-ethylhexanoate, 1-cyclohexyl-1-methylethyl peroxy-2-ethylhexanoate, t-hexyl peroxy-2-ethylhexanoate, t-butyl peroxy-2-ethylhexanoate, t-butyl peroxyisobutyrate, t-butyl peroxymaleic acid, t-butyl peroxylaurate, t-butyl peroxy-3,5,5-trimethylhexanoate, t-butylperoxyisopropyl monocarbonate, t-butylperoxy-2-ethylhexyl monocarbonate, 2,5-dimethyl-2,5-bis(benzoylperoxy)hexane, t-butyl peroxyacetate, t-hexyl peroxybenzoate, t-butyl peroxy-m-toluoylbenzoate, t-butyl peroxybenzoate, bis(t-butylperoxy) isophthalate, t-butylperoxyallyl monocarbonate, and 3,3′,4,4′-tetra(t-butylperoxycarbonyl)benzophenone. These can be used singly or in combination of two or more kinds thereof. Among these organic peroxides, dicumyl peroxide, 2,5-dimethyl-2,5-bis(t-butylperoxy)hexane, α,α′-bis(t-butylperoxy)diisopropylbenzene, and the like are preferred.

Examples of the imidazole compound include 2-ethyl-4-methylimidazole, 2-methylimidazole, 2-ethylimidazole, 2,4-dimethylimidazole, 2-undecylimidazole, 2-heptadecylimidazole, 2-phenylimidazole, 2-phenyl-4-methylimidazole, 1-benzyl-2-methylimidazole, 2-phenyl-4,5-dihydroxymethylimidazole, 2-phenyl-4-methyl-5-hydroxymethylimidazole, 1-vinyl-2-methylimidazole, 1-propyl-2-methylimidazole, 2-isopropylimidazole, 1-cyanomethyl-2-methylimidazole, 1-cyanoethyl-2-ethyl-4-methylimidazole, 1-cyanoethyl-2-undecylimidazole, and 1-cyanoethyl-2-phenylimidazole. Among them, 1-cyanoethyl-2-phenylimidazole and 2-ethyl-4-methylimidazole have high dissolubility in the composition of the present embodiment and are preferable. These can be used singly or in combination of two or more kinds thereof.

Examples of the phosphine compound include primary phosphines, secondary phosphines, and tertiary phosphines. Specific examples of the primary phosphines include alkylphosphines such as ethylphosphine and propylphosphine; and phenylphosphine. Specific examples of the secondary phosphines include dialkylphosphines such as dimethylphosphine and diethylphosphine; and secondary phosphines such as diphenylphosphine, methylphenylphosphine, and ethylphenylphosphine. Examples of the tertiary phosphines include trialkylphosphines such as trimethylphosphine, triethylphosphine, tributylphosphine, and trioctylphosphine; tricyclohexylphosphine, triphenylphosphine, alkyldiphenylphosphine, dialkylphenylphosphine, tribenzylphosphine, tritolylphosphine, tri-p-styrylphosphine, tris(2,6-dimethoxyphenyl)phosphine, tri-4-methylphenylphosphine, tri-4-methoxyphenylphosphine, and tri-2-cyanoethylphosphine. Among them, tertiary phosphines are preferably used. These can be used singly or in combination of two or more kinds thereof.

Examples of the phosphonium salt compound include a tetraphenylphosphonium salt, an alkyltriphenylphosphonium salt, a compound having tetraalkylphosphonium or the like, and specific examples thereof include tetraphenylphosphonium thiocyanate, tetraphenylphosphonium tetra-p-methylphenylborate, butyltriphenylphosphonium thiocyanate, tetraphenylphosphoniumphthalic acid, tetrabutylphosphonium-1,2-cyclohexyldicarboxylic acid, tetrabutylphosphonium-1,2-cyclohexyldicarboxylic acid, and tetrabutylphosphonium lauric acid. These can be used singly or in combination of two or more kinds thereof.

The content of the component (B) is not particularly limited; however, the content is preferably 0.1 to 10.0 parts by mass, more preferably 0.5 to 5.0 parts by mass, and even more preferably 0.7 to 3.0 parts by mass, with respect to 100 parts by mass of the component (A).

### (Component (C): Organic Solvent)

The component (C) is not particularly limited as long as it dissolves the component (A). As the component (C), for example, aromatic hydrocarbons such as benzene, toluene, xylene, and mesitylene; alcohol-based solvents such as methanol, ethanol, isopropyl alcohol, butanol, pentanol, hexanol, propanediol, and phenol; ketone-based solvents such as acetone, methyl isobutyl ketone, methyl ethyl ketone, pentanone, hexanone, cyclopentanone, cyclohexanone, isophorone, and acetophenone; cellosolves such as methyl cellosolve and ethyl cellosolve; ester-based solvents such as methyl acetate, ethyl acetate, butyl acetate, methyl propionate, and butyl formate; and glycol ether-based solvents such as ethylene glycol mono-n-butyl ether, ethylene glycol mono-iso-butyl ether, ethylene glycol mono-tert-butyl ether, diethylene glycol mono-n-butyl ether, diethylene glycol mono-iso-butyl ether, triethylene glycol mono-n-butyl ether, and tetraethylene glycol mono-n-butyl ether, can be used. These can be used singly or in combination of two or more kinds thereof. Among these, it is preferable to use an aromatic hydrocarbon such as toluene or mesitylene, which has high dissolvability for the component (A).

The use amount of the component (C) is not particularly limited; however, usually, the component (C) may be used to the extent that the non-volatile content of the composition of the present embodiment is about 20 to 65% by mass.

Preparation of the composition of the present embodiment is carried out according to a method that is generally employed. Examples of the preparation method include methods such as melt mixing, powder mixing, and solution mixing. Furthermore, in this case, in addition to the essential components of the present embodiment, for example, a mold release agent, a flame retardant, an ion trapping agent, an antioxidant, an adhesion imparting agent, a stress lowering agent, a coloring agent, a coupling agent, an inorganic filler material, and the like may be blended to the extent that does not impair the effects of the present disclosure. In addition, the composition of the present embodiment may include a resin other than the component (A), such as an epoxy resin, an acrylate compound, a vinyl compound, a benzoxazine compound, or a bismaleimide compound.

### (Mold Release Agent)

A mold release agent is added in order to improve releasability from a mold. Regarding the mold release agent, for example, known agents such as carnauba wax, rice wax, candelilla wax, polyethylene, oxidized polyethylene, polypropylene, montanic acid, montan wax, which is ester compounds of montanic acid with a saturated alcohol, 2-(2-hydroxyethylamino)ethanol, ethylene glycol, glycerin, and the like, stearic acid, stearic acid esters, and stearic acid amide, can all be used. These can be used singly or in combination of two or more kinds thereof.

### (Flame Retardant)

A flame retardant is added in order to impart flame retardancy, and known agents can all be used without particular limitation. Examples of the flame retardant include a phosphazene compound, a silicone compound, talc supporting zinc molybdate, zinc oxide supporting zinc molybdate, aluminum hydroxide, magnesium hydroxide, and molybdenum oxide. These can be used singly or in combination of two or more kinds thereof.

### (Ion Trapping Agent)

An ion trapping agent is added in order to capture ionic impurities included in a liquid resin composition and prevent thermal deterioration and moisture absorption deterioration. Regarding the ion trapping agent, known agents can all be used without particular limitation. Examples of the ion trapping agent include hydrotalcites, bismuth hydroxide compounds, and rare earth oxides. These can be used singly or in combination of two or more kinds thereof.

### (Inorganic Filler Material)

Regarding the inorganic filler material, various known materials can be used without particular limitation as long as they are inorganic filler materials that can be used in resin compositions. Examples of the inorganic filler material include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, silica, graphite powder, and boehmite. Among these, silica in particular is preferable because silica is excellent in terms of the low dielectric loss tangent. The inorganic filler materials can be used singly or in combination of two or more kinds thereof.

The average particle diameter of the inorganic filler material may be 50 nm or greater, 100 nm or greater, or 200 nm or greater, and may be 10 μm or less, 5.0 μm or less, 3.0 μm or less, or 1.0 μm or less. The average particle diameter of the inorganic filler material is preferably 100 nm to 10 μm or 50 nm to 5.0 μm, more preferably 100 nm to 3.0 μm, and even more preferably 200 nm to 1.0 μm. When the average particle diameter of the inorganic filler material is in the above-described range, the surface roughness of a sheet can be reduced, and the adhesiveness to base materials such as a polyimide film and a copper foil can be increased.

As the average particle diameter of the inorganic filler material, the value of the median diameter (d50) that is a cumulative particle size of 50% in the volume cumulative particle size distribution is employed. The average particle diameter can be measured by using a laser diffraction scattering type particle size distribution analyzer.

It is preferable that the inorganic filler material is surface-treated, and the inorganic filler material is preferably a material surface-treated with a coupling agent, and more preferably a material surface-treated with a silane coupling agent. When the inorganic filler material is surface-treated, not only it is possible to increase the dispersibility of the inorganic filler material in an organic solvent, but also the surface roughness of the surface of a sheet is further reduced so that the adhesiveness to base materials such as a polyimide film and a copper foil can be increased.

Examples of the coupling agent include a silane coupling agent, a titanium coupling agent, and an aluminum coupling agent. Examples of the silane coupling agent include methacrylsilane, acrylsilane, aminosilane, phenylaminosilane, imidazolesilane, phenylsilane, vinylsilane, and epoxysilane. These can be used singly or in combination of two or more kinds thereof.

In a case where the resin composition contains an inorganic filler material, the content thereof may be 5 to 75% by mass, 5 to 50% by mass, 5 to 35% by mass, or 10 to 30% by mass, based on the total amount (100% by mass) of the solid content (non-volatile content) of the resin composition. When the content of the inorganic filler material is 75% by mass or less, there is a tendency that decrease in the adhesiveness can be suppressed, and when the content is 5% by mass or greater, an effect of reducing the dielectric loss tangent and an effect of improving heat resistance tend to be sufficiently obtained.

### <Cured Product>

A cured product of the present embodiment is a product obtained by curing the composition of the present embodiment. Specifically, the cured product can be obtained by subjecting the composition to a heating treatment at about 150 to 250° C. for about 10 minutes to 3 hours.

The shape of the cured product of the present embodiment is not particularly limited; however, in a case where the cured product is provided for use applications of adhesion of base materials, the cured product can be produced into a sheet shape having a film thickness of usually about 1 to 200 μm, and preferably about 3 to 100 μm, and the film thickness can be appropriately adjusted according to the use applications.

### <Sheet>

A sheet of the present embodiment includes the composition of the present embodiment and a base material. The sheet of the present embodiment is obtained by, for example, applying the composition of the present embodiment on a base material (sheet base material) and drying the composition. Examples of the base material include organic base materials such as polyimide, a polyimide-silica hybrid, polyamide, polyethylene (PE), polypropylene (PP), polyethylene terephthalate (PET), polyethylene naphthalate (PEN), a polymethyl methacrylate resin (PMMA), a polystyrene resin (PSt), a polycarbonate resin (PC), an acrylonitrile-butadiene-styrene resin (ABS), and aromatic polyester resins obtained from ethylene terephthalate, phenol, phthalic acid, hydroxynaphthoic acid, and the like and from para-hydroxybenzoic acid (so-called liquid crystal polymers; manufactured by Kuraray Co., Ltd., “VECSTAR” and the like), and among these, from the viewpoints of heat resistance, dimensional stability, and the like, a polyimide film, particularly a polyimide-silica hybrid film, is preferred. In addition, as the base material, inorganic base materials such as glass; metals such as iron, aluminum, Alloy 42, and copper; and inorganic base materials such as ITO, silicon, and silicon carbide may also be used. The thickness of the base material can be appropriately set according to the use applications.

### <Laminated Body>

A laminated body of the present embodiment is obtained by allowing another base material to be thermocompression bonded to an adhesive surface (surface on the side of a layer formed by using the composition of the present embodiment) of the above-described sheet. As the base material, for example, organic base materials such as polyimide, a polyimide-silica hybrid, polyamide, polyethylene (PE), polypropylene (PP), polyethylene terephthalate (PET), polyethylene naphthalate (PEN), a polymethyl methacrylate resin (PMMA), a polystyrene resin (PSt), a polycarbonate resin (PC), an acrylonitrile-butadiene-styrene resin (ABS), and aromatic polyester resins obtained from ethylene terephthalate, phenol, phthalic acid, hydroxynaphthoic acid, and the like and from para-hydroxybenzoic acid (so-called liquid crystal polymers; manufactured by Kuraray Co., Ltd., “VECSTAR” and the like) can be used. In addition, as the base material, inorganic base materials such as glass; metals such as iron, aluminum, Alloy 42, and copper; ITO; silicon; and silicon carbide are suitable. The thickness of the base material can be appropriately set according to the use applications. Furthermore, the laminated body may be subjected to a heating treatment.

### <Printed Board and Printed Wiring Board>

A printed board of the present embodiment is a printed board that uses the above-described sheet, or a printed board that uses the above-described laminated body. The printed board of the present embodiment is obtained by, for example, further bonding an adhesive surface of the above-described sheet to an inorganic base material surface of the above-described laminated body. For the printed board, it is preferable to use a polyimide film as an organic base material, and a metal foil (particularly a copper foil) as an inorganic base material. Then, a printed wiring board is obtained by subjecting the metal surface of such a printed board to a soft etching treatment to form circuits, further bonding the above-described sheet thereon, and hot pressing them together.

### EXAMPLES

Hereinafter, the present disclosure will be specifically described by way of Examples and Comparative Examples; however, the present disclosure is not intended to be limited to these. Incidentally, in each example, the units “parts” and “percent (%)” are on a mass basis, unless particularly stated otherwise.

### [Molecular Weight]

The molecular weight of a maleimide resin was measured by GPC (gel permeation chromatography). 50 μL of a sample obtained by dissolving the maleimide resin in tetrahydrofuran (THF) to a concentration of 3% by mass, was injected into columns (one unit of GL-R420 (manufactured by Hitachi High-Tech Fielding Corporation), one unit of GL-R430 (manufactured by Hitachi High-Tech Fielding Corporation), and one unit of GL-R440 (manufactured by Hitachi High-Tech Fielding Corporation)) warmed to 30° C., and measurement was performed by using THF as a developing solvent under the conditions of a flow rate of 1.6 mL/min. An L-3350 RI detector (manufactured by Hitachi, Ltd.) was used as a detector, and the weight average molecular weight (Mw) was converted from the elution time on the basis of a molecular weight-elution time curve created by using polystyrene standards (manufactured by Tosoh Corporation).

### <Synthesis of Maleimide Resin>

### Synthesis Example 1

Into a 1 L flask container equipped with a condenser, a nitrogen inlet tube, a thermocouple, and a stirring machine, 29.67 parts by mass of 4,4′-(hexafluoroisopropylidene)diphthalic anhydride (manufactured by Daikin Industries, Ltd., a compound represented by Formula (1)), 129.37 parts by mass of T-SOL 100 (manufactured by ENEOS Corporation, an aromatic high-boiling point solvent), and 27.81 parts by mass of SOLMIX A-11 (manufactured by Japan Alcohol Trading CO., LTD., an alcohol-based solvent) were introduced. After the introduction, temperature was raised to 80° C., the mixture was kept for 0.5 hours, and 33.50 parts by mass of a dimer diamine (trade name “PRIAMINE 1075”, manufactured by Croda Japan K.K.) was added dropwise thereto. After the dropwise addition, 5.30 parts by mass of 4,4′-methylenedianiline (manufactured by FUJIFILM Wako Pure Chemical Corporation) was added thereto. After the addition, 1.71 parts by mass of an aqueous solution of methanesulfonic acid (manufactured by BASF, trade name “Lutropur MSA”) was added thereto. Thereafter, temperature was raised to 160° C. After the temperature rise, 40.00 parts by mass of toluene (manufactured by Yamaichi Chemical Industries Co., Ltd.) was added thereto, a dehydration ring-closing reaction was performed at 160° C. for 1 hour, water and alcohol in the reaction liquid were removed, and a polyimide resin as an intermediate was obtained. Subsequently, the obtained polyimide resin was cooled to 130° C., 6.56 parts by mass of maleic anhydride (manufactured by FUSO CHEMICAL CO., LTD.) was added thereto, temperature was raised to 160° C., a dehydration ring-closing reaction was performed at 160° C. for 4 hours, water in the reaction liquid was removed, and a maleimide resin (bismaleimide resin) was obtained.

The obtained bismaleimide resin was fed into a separatory funnel, 500 parts by mass of pure water was introduced thereinto, and the separatory funnel was shaken and left to stand still. After standing, after an aqueous layer and an organic layer were separated, only the organic layer was collected. The collected organic layer was introduced into a 1 L glass container equipped with a condenser, a nitrogen inlet tube, a thermocouple, a stirring machine, and a vacuum pump, temperature was raised to 88 to 93° C., water was removed, subsequently temperature was raised to 100° C., the solvent was removed for 0.5 hours in a state in which pressure was reduced by 0.1 MPa from the atmospheric pressure, and a bismaleimide resin (A-1) of the component (A) was obtained.

### Synthesis Example 2

A bismaleimide resin (A-2) was obtained in the same manner as in Synthesis Example 1, except that the blending amount of each component was changed as shown in Table 1.

### Synthesis Examples 3 and 4

Bismaleimide resins (A-3) and (A-4) were obtained in the same manner as in Synthesis Example 1, except that 4,4′-methylenedianiline was changed to norbornanediamine (manufactured by Mitsui Fine Chemicals, Inc.), and the blending amount of each component was changed as shown in Table 1.

### Synthesis Example 5

A bismaleimide resin (A-5) was obtained in the same manner as in Synthesis Example 1, except that 4,4′-methylenedianiline was changed to 1,3-diaminopropane (manufactured by FUJIFILM Wako Pure Chemical Corporation), and the blending amount of each component was changed as shown in Table 1.

### Synthesis Examples 6 and 7

Bismaleimide resins (A-6) and (A-7) were obtained in the same manner as in Synthesis Example 1, except that 4,4′-methylenedianiline was changed to 2-methyl-1,5-diaminopentane (manufactured by Tokyo Chemical Industry Co., Ltd.), and the blending amount of each component was changed as shown in Table 1.

### Synthesis Examples 8 and 9

Bismaleimide resins (A-8) and (A-9) were obtained in the same manner as in Synthesis Example 1, except that 4,4′-methylenedianiline was changed to norbornanediamine (manufactured by Mitsui Fine Chemicals, Inc.), 4,4′-(hexafluoroisopropylidene)diphthalic anhydride was changed to 1,3,3a,4,5,9b-hexahydro-5-(tetrahydro-2,5-dioxo-3-furanyl)naphtho[1,2-C]furan-1,3-dione (manufactured by New Japan Chemical Co., Ltd., trade name “TDA-100”, a compound represented by Formula (2)), and the blending amount of each component was changed as shown in Table 1.

### Synthesis Examples 10 and 11

Bismaleimide resins (A-10) and (A-11) were obtained in the same manner as in Synthesis Example 1, except that 4,4′-methylenedianiline was changed to 2-methyl-1,5-diaminopentane (manufactured by Tokyo Chemical Industry Co., Ltd.), 4,4′-(hexafluoroisopropylidene)diphthalic anhydride was changed to 1,3,3a,4,5,9b-hexahydro-5-(tetrahydro-2,5-dioxo-3-furanyl)naphtho[1,2-C]furan-1,3-dione (manufactured by New Japan Chemical Co., Ltd., trade name “TDA-100”, a compound represented by Formula (2)), and the blending amount of each component was changed as shown in Table 1.

### Synthesis Example 12

A bismaleimide resin (A-12) was obtained in the same manner as in Synthesis Example 1, except that 4,4′-methylenedianiline was not used, 4,4′-(hexafluoroisopropylidene)diphthalic anhydride was changed to pyromellitic anhydride (manufactured by Daicel Corporation, trade name “PMDA”), and the blending amount of each component was changed as shown in Table 1.

### Synthesis Example 13

A bismaleimide resin (A-13) was obtained in the same manner as in Synthesis Example 1, except that 4,4′-methylenedianiline was changed to 1,3-bis[2-(4-aminophenyl)-2-propyl]benzene (manufactured by Tokyo Chemical Industry Co., Ltd., also known as “Bisaniline M”), 4,4′-(hexafluoroisopropylidene)diphthalic anhydride was changed to 1,3,3a,4,5,9b-hexahydro-5(tetrahydro-2,5-dioxo-3-furanyl)naphtho[1,2-C]furan-1,3-dione (manufactured by New Japan Chemical Co., Ltd., trade name “TDA-100”, a compound represented by Formula (2)), and the blending amount of each component was changed as shown in Table 1.

### Synthesis Example 14

A bismaleimide resin (A-14) was obtained in the same manner as in Synthesis Example 1, except that 4,4′-methylenedianiline was changed to norbornanediamine (manufactured by Mitsui Fine Chemicals, Inc.), 4,4′-(hexafluoroisopropylidene)diphthalic anhydride was changed to 5-(2,5-dioxotetrahydrofuryl)-3-methyl-3-cyclohexene-1,2-dicarboxylic acid anhydride (manufactured by ZHEJIANG ALPHARM CHEMTECH, Ltd., trade name “AMC-550”, a compound represented by Formula (6)), and the blending amount of each component was changed as shown in Table 1.

### Synthesis Example 15

A bismaleimide resin (A-15) was obtained in the same manner as in Synthesis Example 1, except that 4,4′-methylenedianiline was changed to norbornanediamine (manufactured by Mitsui Fine Chemicals, Inc.), 4,4′-(hexafluoroisopropylidene)diphthalic anhydride was changed to 4,4′-oxydiphthalic anhydride (manufactured by Tokyo Chemical Industry Co., Ltd., also known as “ODPA”), and the blending amount of each component was changed as shown in Table 1.

TABLE 1

| | | Bismaleimide resin | | | | | | | |
|---|---|---|---|---|---|---|---|---|---|
| | | A-1 | A-2 | A-3 | A-4 | A-5 | A-6 | A-7 | A-8 |
| Component (a1) | Compound of Formula (1) | 29.67 | 33.94 | 29.70 | 33.94 | 31.82 | 31.82 | 36.06 | — |
| | Compound of Formula (2) | — | — | — | — | — | — | — | 24.35 |
| | Compound of Formula (6) | — | — | — | — | — | — | — | — |
| | ODPA | — | — | — | — | — | — | — | — |
| | Pyromellitic anhydride | — | — | — | — | — | — | — | — |
| Component (a2) | Dimer diamine | 33.50 | 27.35 | 33.50 | 27.35 | 35.89 | 35.89 | 29.06 | 40.68 |
| | 4,4′-methylenedianiline | 5.30 | 10.10 | — | — | — | — | — | — |
| | Norbornanediamine | — | — | 4.13 | 7.86 | — | — | — | 5.01 |
| | 1,3-diaminopropane | — | — | — | — | 2.12 | — | — | — |
| | 2-methyl-1,5-diaminopentane | — | — | — | — | — | 3.33 | 6.29 | — |
| | Bisaniline M | — | — | — | — | — | — | — | — |
| Component (a3) | Maleic anhydride | 6.56 | 7.49 | 6.56 | 7.49 | 7.02 | 7.02 | 7.96 | 7.96 |
| Catalyst | Aqueous solution of | 1.71 | 1.96 | 1.71 | 1.96 | 1.84 | 1.84 | 2.08 | 2.08 |
| | methanesulfonic acid | | | | | | | | |
| Solvent | T-SOL 100 | 129.37 | 135.04 | 127.18 | 130.87 | 132.00 | 134.24 | 135.23 | 132.69 |
| | SOLMIX A-11 | 27.81 | 29.45 | 27.41 | 28.70 | 28.59 | 29.00 | 29.79 | 29.33 |
| | Toluene | 40.00 | 40.00 | 40.00 | 40.00 | 40.00 | 40.00 | 40.00 | 40.00 |

| | | | | | | | | |
|---|---|---|---|---|---|---|---|---|
| Mw | 14500 | 10300 | 15100 | 12000 | 12300 | 15100 | 13700 | 10900 |
| Number of moles of component (a1)/number of | 0.75 | 0.75 | 0.75 | 0.75 | 0.75 | 0.75 | 0.75 | 0.75 |
| moles of component (a2) | | | | | | | | |

| | | Bismaleimide resin | | | | | | |
|---|---|---|---|---|---|---|---|---|
| | | A-9 | A-10 | A-11 | A-12 | A-13 | A-14 | A-15 |
| Component (a1) | Compound of Formula (1) | — | — | — | — | — | — | — |
| | Compound of Formula (2) | 25.79 | 24.35 | 27.22 | — | 27.46 | — | — |
| | Compound of Formula (6) | — | — | — | — | — | 27.34 | — |
| | ODPA | — | — | — | — | — | — | 27.16 |
| | Pyromellitic anhydride | — | — | — | 17.36 | — | — | — |
| Component (a2) | Dimer diamine | 30.76 | 40.68 | 32.47 | 56.97 | 32.76 | 37.03 | 43.87 |
| | 4,4′-methylenedianiline | — | — | — | — | — | — | — |
| | Norbornanediamine | 8.84 | — | — | — | — | 10.64 | 5.40 |
| | 1,3-diaminopropane | — | — | — | — | — | — | — |
| | 2-methyl-1,5-diaminopentane | — | 3.77 | 7.03 | — | — | — | — |
| | Bisaniline M | — | — | — | — | 21.02 | — | — |
| Component (a3) | Maleic anhydride | 8.43 | 7.96 | 8.90 | 7.80 | 8.97 | 10.15 | 8.58 |
| Catalyst | Aqueous solution of | 2.20 | 2.08 | 2.33 | 2.04 | 2.35 | 2.65 | 2.24 |
| | methanesulfonic acid | | | | | | | |
| Solvent | T-SOL 100 | 124.21 | 130.40 | 126.83 | 140.61 | 113.94 | 104.43 | 104.95 |
| | SOLMIX A-11 | 28.10 | 28.92 | 28.88 | 30.67 | 20.72 | 18.99 | 19.08 |
| | Toluene | 40.00 | 40.00 | 40.00 | 40.00 | 40.00 | 40.00 | 40.00 |

| | | | | | | | |
|---|---|---|---|---|---|---|---|
| Mw | 9200 | 11400 | 9100 | 16800 | 6,900 | 8,600 | 13,400 |
| Number of moles of component (a1)/number of | 0.75 | 0.75 | 0.75 | 0.75 | 0.75 | 0.75 | 0.75 |
| moles of component (a2) | | | | | | | |

### Examples 1 to 13 and Comparative Examples 1 and 2

### <Creation of Resin Composition and Cured Sheet>

A maleimide resin composition was prepared by blending each of the components shown below in the composition shown in Table 2. Next, the maleimide resin composition was applied on a Cu foil (manufactured by Furukawa Electric Co., Ltd., product name: FZ-WS-18) b using an applicator such that the thickness after drying would be 100 μm, and the resultant was subjected to a drying treatment at 130° C. for 30 minutes in a dryer. Subsequently, a curing treatment was performed at 200° C. for 2 hours in the dryer. After curing, the product was cooled to room temperature, subsequently the copper foil was removed by etching with an aqueous solution of ammonium persulfate, and the resultant was dried at 110° C. for 30 minutes to create a cured sheet.

### Component (A): Maleimide Resin

Bismaleimide resins (A-1) to (A-15) created in the above-described Synthesis Examples 1 to 12

### Component (B): Polymerization Initiator

(B-1) DCP (manufactured by NOF CORPORATION, trade name “PERCUMIL D”, dicumyl peroxide)

### Component (C): Organic Solvent

(C-1) Toluene (manufactured by Yamaichi Chemical Industries Co., Ltd.)

### [Measurement of Elastic Modulus and Tg]

A test piece having a sample size of 20 mm×10 mm was created by using a cured sheet, and the elastic modulus at 20° C. and Tg (tan 6 peak) were measured using a dynamic viscoelasticity measuring apparatus (manufactured by SII NanoTechnology, Inc., trade name “DMS6100”) under the conditions of a frequency of 1 Hz, a measurement temperature of −40° C. to 220° C., and a temperature increase rate of 10° C./min. The results are presented in Table 2.

### [Coefficient of Linear Expansion (CTE)]

A test piece having a size of 30 mm×4 mm was created from a cured sheet. Using this test piece, the coefficient of linear expansion (CTE) was measured by using a thermomechanical analyzer (trade name “TMA/SS7100”, manufactured by Hitachi High-Tech Science Corporation). The measurement mode was a tensile mode, the measurement load was 50 mN, the measurement atmosphere was an air atmosphere, the temperature increase rate was set to 5° C./min, and the measurement results at 110 to 160° C. in the second run was taken as CTE. The results are presented in Table 2.

### [5% Weight Loss Temperature]

6.0 to 10.0 mg of a cured sheet was weighed in an open-type sample container (manufactured by Seiko Electronics Co., Ltd., trade name “P/N SSC000E030”), measurement was performed under the conditions of a nitrogen flow rate of 300 mL/min and a temperature increase rate of 10° C./min, and the 5% weight loss temperature (T_{d5}) was measured. For the measuring apparatus, TG/DTA7200 (manufactured by Hitachi High-Tech Science Corporation) was used. The results are presented in Table 2.

### [Evaluation of Dielectric Characteristics]

A test piece having a sample size of 50 mm×100 mm was created by using a cured sheet, and the dielectric constant (Dk) at 10 GHz and the dielectric loss tangent (Df) were measured using an SPDR dielectric resonator (manufactured by Agilent Technologies). From the measurement results, evaluation was performed on the basis of the following determination criteria. In a case where the evaluation result is A or B, it can be said that the dielectric characteristics are sufficiently low. The results are presented in Table 2.

### <Determination Criteria for Dk>

A: less than 2.5
B: 2.5 or greater and less than 2.8
C: 2.8 or greater

### <Determination Criteria for Df>

A: less than 0.0030
B: 0.0030 or greater and less than 0.0050
C: 0.0050 or greater

TABLE 2

| Item | | Example 1 | Example 2 | Example 3 | Example 4 | Example 5 | Example 6 | Example 7 | Example 8 | Example 9 |
|---|---|---|---|---|---|---|---|---|---|---|
| Component (A) | (A-1) | 100 | — | — | — | — | — | — | — | — |
| maleimide resin | (A-2) | — | 100 | — | — | — | — | — | — | — |
| | (A-3) | — | — | 100 | — | — | — | — | — | — |
| | (A-4) | — | — | — | 100 | — | — | — | — | — |
| | (A-5) | — | — | — | — | 100 | — | — | — | — |
| | (A-6) | — | — | — | — | — | 100 | — | — | — |
| | (A-7) | — | — | — | — | — | — | 100 | — | — |
| | (A-8) | — | — | — | — | — | — | — | 100 | — |
| | (A-9) | — | — | — | — | — | — | — | — | 100 |
| | (A-10) | — | — | — | — | — | — | — | — | — |
| | (A-11) | — | — | — | — | — | — | — | — | — |
| | (A-12) | — | — | — | — | — | — | — | — | — |
| | (A-13) | — | — | — | — | — | — | — | — | — |
| | (A-14) | — | — | — | — | — | — | — | — | — |
| | (A-15) | — | — | — | — | — | — | — | — | — |
| Component (B) | DCP | 0.74 | 0.81 | 0.80 | 0.74 | 0.78 | 0.85 | 0.76 | 0.88 | 0.77 |
| polymerization | | | | | | | | | | |
| initiator | | | | | | | | | | |
| Component (C) | Toluene | — | 8.4 | 6.2 | — | 4.2 | 13.0 | 1.8 | 17.6 | 3.0 |
| organic solvent | | | | | | | | | | |
| Evaluation item | Elastic modulus | 1.1 | 2.1 | 1.8 | 1.2 | 1.0 | 1.2 | 1.3 | 1.4 | 1.7 |
| | (GPa) | | | | | | | | | |
| | Tg (° C.) | 69.9 | 121.6 | 77.7 | 113.8 | 66.8 | 68.3 | 87.5 | 72.7 | 114.7 |
| | CTE (ppm/° C.) | 94 | 134 | 123 | 84 | 69 | 44 | 81 | 74 | 102 |
| | T_{d5} (° C.) | 418 | 425 | 412 | 418 | 414 | 410 | 421 | 399 | 405 |
| | Dk | A | B | A | A | A | A | A | A | A |
| | Df | A | A | A | A | B | B | B | A | B |

| | | | | | | Comparative | Comparative |
|---|---|---|---|---|---|---|---|
| Item | | Example 10 | Example 11 | Example 12 | Example 13 | Example 1 | Example 2 |
| Component (A) | (A-1) | — | — | — | — | — | — |
| maleimide resin | (A-2) | — | — | — | — | — | — |
| | (A-3) | — | — | — | — | — | — |
| | (A-4) | — | — | — | — | — | — |
| | (A-5) | — | — | — | — | — | — |
| | (A-6) | — | — | — | — | — | — |
| | (A-7) | — | — | — | — | — | — |
| | (A-8) | — | — | — | — | — | — |
| | (A-9) | — | — | — | — | — | — |
| | (A-10) | 100 | — | — | — | — | — |
| | (A-11) | — | 100 | — | — | — | — |
| | (A-12) | — | — | — | — | 100 | — |
| | (A-13) | — | — | 100 | — | — | — |
| | (A-14) | — | — | — | 100 | — | — |
| | (A-15) | — | — | — | — | — | 100 |
| Component (B) | DCP | 0.82 | 0.74 | 0.77 | 0.80 | 0.83 | 0.85 |
| polymerization | | | | | | | |
| initiator | | | | | | | |
| Component (C) | Toluene | 8.8 | — | 2.6 | 6.6 | 10.4 | 13.6 |
| organic solvent | | | | | | | |
| Evaluation item | Elastic modulus | 1.3 | 1.4 | 1.3 | 1.4 | 0.4 | 0.8 |
| | (GPa) | | | | | | |
| | Tg (° C.) | 64.8 | 88.6 | 116.0 | 93.0 | 38.8 | 46.0 |
| | CTE (ppm/° C.) | 103 | 97 | 97 | 110 | 200 | 112 |
| | T_{d5} (° C.) | 394 | 396 | 408 | 397 | 402 | 405 |
| | Dk | A | A | A | A | A | B |
| | Df | B | B | A | A | A | A |

As is obvious from the results shown in Table 2, it could be verified that the maleimide resin compositions of Examples have excellent low dielectric characteristics (low Dk and low Df), a high elastic modulus, a high Tg, and a low CTE as the cured product characteristics. Therefore, it can be expected to dramatically improve the characteristics of sealing materials for laminated boards such as printed boards and electronic components such as semiconductors, by using the maleimide resin compositions of the present disclosure.

1. A resin composition comprising a maleimide resin (A) obtained by reacting a tetracarboxylic acid dianhydride (a1), a diamine (a2), and maleic anhydride (a3),
wherein the tetracarboxylic acid dianhydride (a1) contains at least one of a compound represented by the following Formula (1), a compound represented by the following Formula (2), and a compound represented by the following Formula (6), and
the diamine (a2) contains a dimer diamine and a second diamine other than a dimer diamine.

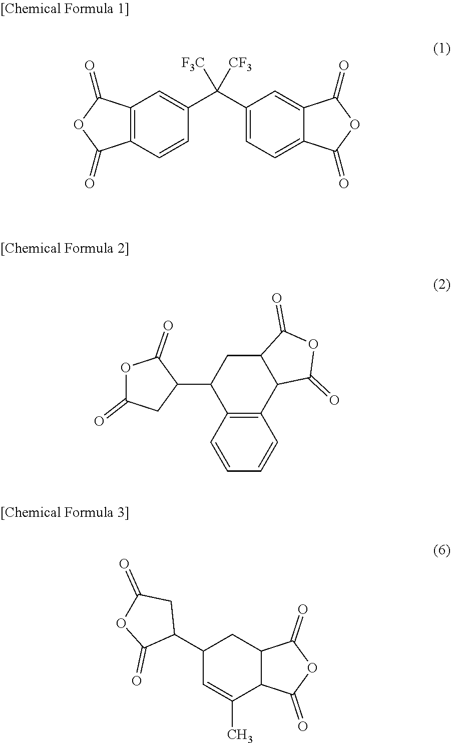 [SMILES: O=C1OC(=O)c2cc(C(c3ccc4c(c3)C(=O)OC4=O)(C(F)(F)F)C(F)(F)F)ccc21 ; O=C1CC(C2CC3C(=O)OC(=O)C3c3ccccc32)C(=O)O1 ; CC1=CC(C2CC(=O)OC2=O)CC2C(=O)OC(=O)C12]

2. The resin composition according to claim 1, wherein the second diamine includes at least one selected from the group consisting of 1,3-diaminopropane, norbornanediamine, 4,4′-methylenedianiline, and 1,3-bis[2-(4-aminophenyl)-2-propyl]benzene.

3. The resin composition according to claim 1, wherein the dimer diamine includes at least one of a compound represented by the following General Formula (3) and a compound represented by the following General Formula (4): 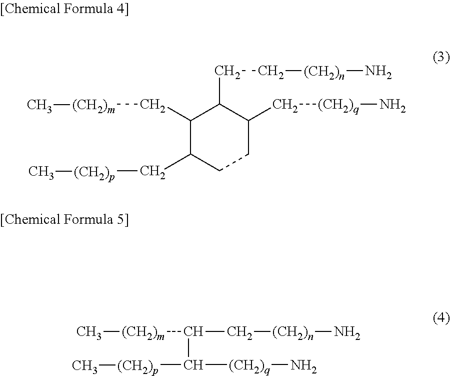
[wherein in Formula (3) and Formula (4), m, n, p, and q each represent an integer of 1 or greater selected such that m+n=6 to 17 and p+q=8 to 19; and a bond indicated by a broken line means a carbon-carbon single bond or a carbon-carbon double bond, provided that in a case where the bond indicated by a broken line is a carbon-carbon double bond, Formula (3) and Formula (4) form structures in which the number of hydrogen atoms bonded to each carbon atom constituting the carbon-carbon double bond is smaller by 1 than the number indicated in Formula (3) and Formula (4).]

4. The resin composition according to claim 1, wherein the maleimide resin (A) has a weight average molecular weight of 3000 to 25000.

5. A cured product of the resin composition according to claim 1.

6. A sheet comprising the resin composition according to claim 1 and a base material.

7. The sheet according to claim 6, wherein the base material is an organic base material.

8. The sheet according to claim 6, wherein the base material is an inorganic base material.

9. A laminated body obtained by allowing another base material to be thermocompression bonded to an adhesive surface of the sheet according to claim 6.

10. A printed wiring board obtained by using the sheet according to claim 6.

11. A printed wiring board obtained by using the laminated body according to claim 9.
